(19) United States
(12) Patent Application Publication
(10) Pub. No.: US 2011/0117279 A1
(43) Pub. Date: May 19, 2011

(54) THIN FILM FORMING METHOD AND FILM FORMING APPARATUS

(75) Inventors: Yasuharu Shinokawa, Osaka (JP); Kazuyoshi Honda, Osaka (JP); Yuma Kamiyama, Kyoto (JP); Masahiro Yamamoto, Osaka (JP); Tomofumi Yanagi, Osaka (JP)

(73) Assignee: PANASONIC CORPORATION, Kadoma-shi, Osaka (JP)

(21) Appl. No.: 12/918,275

(22) PCT Filed: Feb. 17, 2009
(86) PCT No.: PCT/JP2009/000644

§ 371 Date: Aug. 18, 2010

(30) Foreign Application Priority Data
Feb. 20, 2008 (JP) 2008-038239

(51) Int. Cl. B05D 3/00; C23C 14/50

(52) U.S. Cl. 427/295; 118/50; 427/294

(57) ABSTRACT

A thin film forming apparatus (100) includes: a vacuum chamber (1); a substrate transfer mechanism (40) that is provided in the vacuum chamber (1) and feeds an elongated substrate (8) to a predetermined film forming section (4) that faces a film forming source (27); an endless belt (10) capable of moving in accordance with the feeding of the substrate (8) by the substrate transfer mechanism (40), and configured to define, along an outer peripheral surface of the endless belt itself, a transfer path of the substrate (8) in the film forming section (4) so that a thin film is formed on a surface of the substrate (8) that is being transferred linearly; a through-hole (16) formed in the endless belt (10); and a substrate cooling unit (30) for introducing a cooling gas between the endless belt (10) and a back surface of the substrate (8) through the through-hole (16) from a side of an inner peripheral surface of the endless belt (10) that is moving.

### TECHNICAL FIELD

The present invention relates to a thin film forming apparatus and a thin film forming method.

### BACKGROUND ART

Recently, thin film techniques have been used widely to enhance the performance of devices and to reduce the size thereof. Thin film devices not only provide direct benefits to users but also play an important role in environmental aspects such as protection of earth resources and reduction in power consumption.

Film formation techniques for high-rate deposition are essential to increase the productivity of thin films. Attempts have been made to increase the deposition rate in various film formation methods such as vacuum vapor deposition, sputtering, ion plating, and chemical vapor deposition (CVD). A take-up type thin film manufacturing method has been known as a method of manufacturing a large number of thin films continuously. The take-up type thin film manufacturing method is a method for forming thin films on an elongated substrate that is being transferred from a feed roller to a take-up roller.

In the take-up type thin film manufacturing method, attention must be paid to the cooling of the substrate. For example, in the case of vacuum vapor deposition, radiant heat from an evaporation source and thermal energy of evaporated particles are applied to the substrate and increase the temperature of the substrate. To prevent the substrate from being deformed or melted by heat, the substrate is cooled.

As a means for cooling the substrate, cylindrical cans with large heat capacities are used widely. Specifically, films are formed on a substrate that is moving along a can placed on the transfer path of the substrate. This method allows the heat to escape to the can, an excessive rise in the temperature of the substrate can be prevented. For efficient cooling, it is desirable to ensure sufficiently the thermal contact between the substrate and the can.

An example of a method for ensuring the thermal contact between a substrate and a can in a vacuum atmosphere is the use of a cooling gas. JP 01 (1989)-152262 A describes a technique for introducing a gas between a substrate and a can (rotating drum) to promote heat transfer therebetween. The gas, however, does not spread over the surface of the substrate simply by spraying the gas to the position where the contact between the can and the substrate begins (or ends). Therefore, the cooling effect of the gas is limited.

On the other hand, in some cases, a belt is used instead of a can to transfer a substrate. When a can is used, a film is formed on a substrate that is bent in an arc. In contrast, when a belt is used, a substrate can be transferred linearly a long distance. A film can be formed on the substrate that is held flat by the belt. Therefore, the transfer by means of the belt is more advantageous than the transfer by means of the can in terms of the material use efficiency.

### DISCLOSURE OF THE INVENTION

When the belt is used, however, it is difficult to cool the substrate. This is because in the linear transfer section of the substrate, forces hardly act in the normal direction between the substrate and the belt, which makes it difficult to ensure the thermal contact between the substrate and the belt. This problem is all the more serious in the case of vacuum film formation because the air as a heat carrier is thin. There is another method for promoting the cooling of a substrate by cooling the inner peripheral surface of a belt, as described in JP 06 (1994)-145982 A, but sufficient cooling cannot be expected due to poor heat transfer. It is an object of the present invention to provide a technique for cooling a substrate that is being transferred linearly.

More specifically, the present invention provides a thin film forming apparatus including:

a vacuum chamber;

a substrate transfer mechanism that is provided in the vacuum chamber and feeds an elongated substrate to a predetermined film forming section that faces a film forming source;

an endless belt capable of moving in accordance with the feeding of the substrate by the substrate transfer mechanism, and configured to define, along an outer peripheral surface of the endless belt itself, a transfer path of the substrate in the film forming section so that a thin film is formed on a surface of the substrate that is being transferred linearly;

a through-hole formed in the endless belt; and

a substrate cooling unit for introducing a cooling gas between the endless belt and a back surface of the substrate through the through-hole from a side of an inner peripheral surface of the endless belt that is moving.

In another aspect, the present invention provides a method of forming a thin film on an elongated substrate in a vacuum. This method includes the steps of:

depositing a material from a film forming source on a surface of the substrate that is being transferred linearly along an outer peripheral surface of an endless belt that defines a transfer path of the substrate; and

introducing a cooling gas between the endless belt and a back surface of the substrate through a through-hole formed in the endless belt, while carrying out the step of depositing the material.

According to the present invention, a through-hole is formed in the endless belt for transferring the substrate, and a cooling gas is introduced between the endless belt and the back surface of the substrate through the through-hole. With this configuration, the substrate that is being transferred linearly can be cooled sufficiently without having to ensure the close contact between the endless belt and the substrate. In addition, since the substrate, on which a film is being formed, can be cooled, only a small amount of cooling gas can produce a significant cooling effect. This is advantageous in achieving a high deposition rate while maintaining the pressure in the vacuum chamber at a suitable level for film formation. A reduction in the amount of cooling gas used also is preferable from the viewpoint of reducing the load on the vacuum pump.

In this description, the phrase “linear transfer of a substrate” means the transfer of the substrate by means of an endless belt. More specifically, it means the transfer of the substrate along the flat portion (a portion that is not in contact with the roller and the can) of the endless belt.

### BRIEF DESCRIPTION OF DRAWINGS

FIG. 1 is a schematic cross-sectional view of a thin film forming apparatus according to a first embodiment of the present invention.

FIG. 2A is a partially enlarged view of FIG. 1.

FIG. 2B is a plan view of an endless belt.

FIG. 2C is a partially enlarged view of FIG. 2A.

FIG. 3A is a schematic cross-sectional view of a modified cabinet.

FIG. 3B is a top view of the cabinet in FIG. 3A.

FIG. 4 is a schematic cross-sectional view of another modified cabinet.

FIG. 5A is a plan view showing an arrangement of through-holes formed in the endless belt.

FIG. 5B is a plan view showing another arrangement of through-holes.

FIG. 5C is a plan view showing still another arrangement of through-holes.

FIG. 5D is a plan view showing further still another arrangement of through-holes.

FIG. 6 is a diagram illustrating the function of through-holes formed in the endless belt.

FIG. 7 is a schematic cross-sectional view of a thin film forming apparatus according to a second embodiment.

### BEST MODE FOR CARRYING OUT THE INVENTION

### First Embodiment

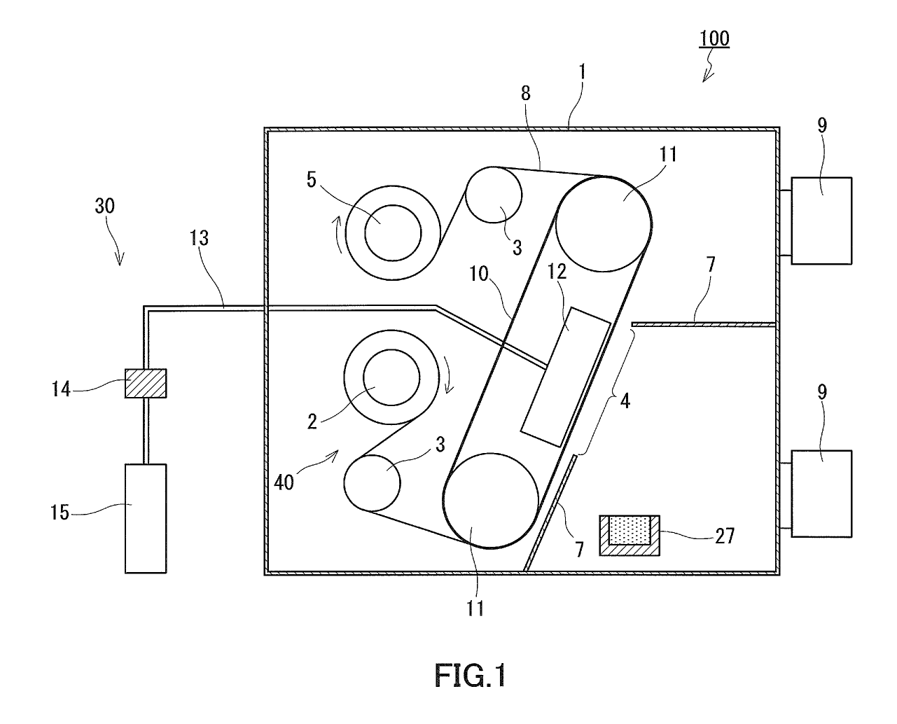

Hereinafter, one embodiment of the present invention will be described with reference to the accompanying drawings. As shown in FIG. 1, a thin film forming apparatus 100 of the present embodiment includes a vacuum chamber 1, a film forming source 27, a shielding plate 7, a substrate transfer mechanism 40, an endless belt 10, a can (cooling can) 11, and a substrate cooling unit 30. The film forming source 27, the substrate transfer mechanism 40, and the endless belt 10 are disposed in the vacuum chamber 1. A part of the substrate cooling unit 30 is located in the vacuum chamber 1, and the remaining part thereof is located outside the vacuum chamber 1. A vacuum pump 9 is connected to the vacuum chamber 1.

The substrate cooling unit 30 has a cabinet 12, a cooling gas supply channel (cooling gas supply pipe) 13, a flow controller 14, and a gas supply source 15. The cabinet 12 is provided in proximity to the endless belt 10 in a space surrounded by the endless belt 10, and opens toward the inner peripheral surface of the endless belt 10 in a section where the transfer path of the substrate 8 is defined. One end of the cooling gas supply channel 13 is connected to the cabinet 12, and the other end thereof is connected to the cooling gas source 15 that is located outside the vacuum chamber 1. The flow controller 14 is provided in the cooling gas supply channel 13. The flow controller 14 can control the amount of cooling gas to be supplied from the cooling gas source 15 to the cabinet 12 through the cooling gas supply channel 13.

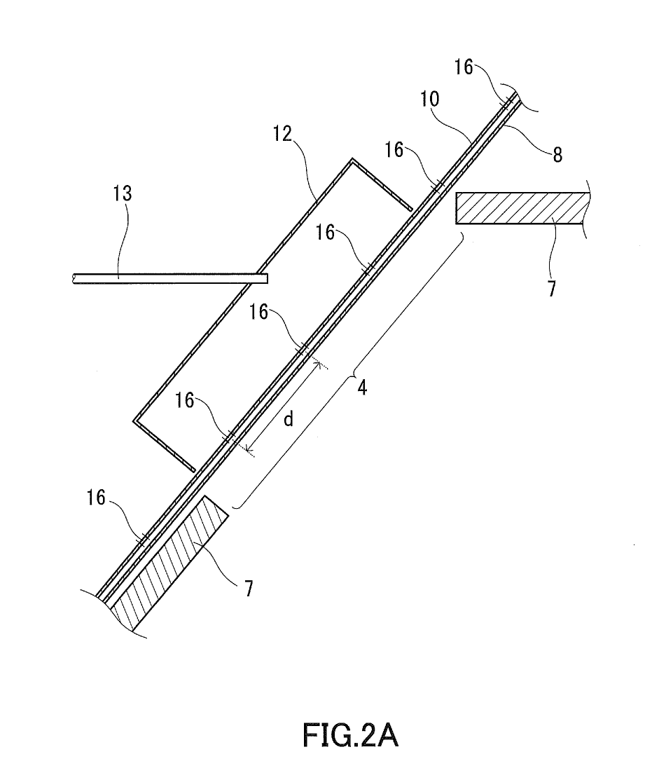

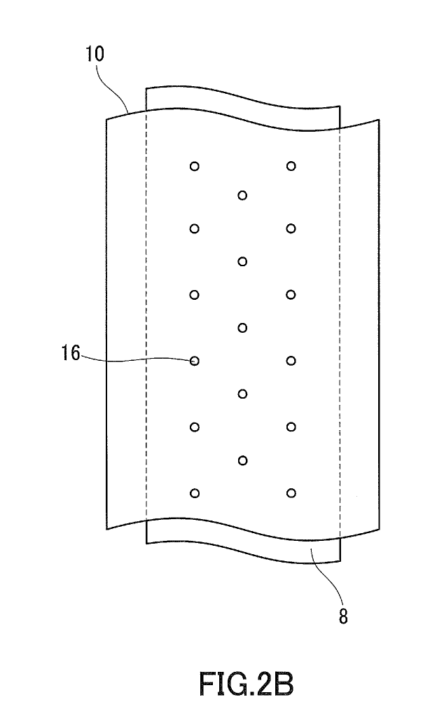

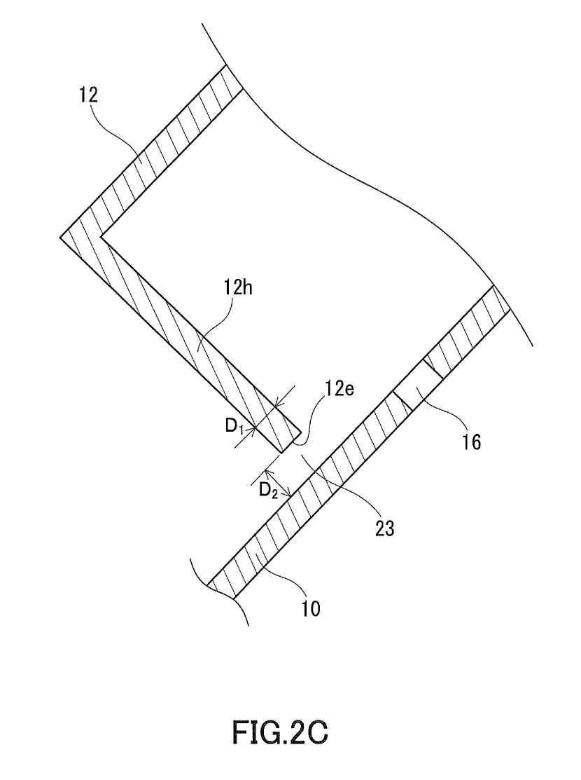

The endless belt 10 defines a part of the transfer path of the substrate 8 along the outer peripheral surface of the endless belt itself. As shown in FIG. 2A, through-holes 16 are formed in the endless belt 10 in the thickness direction thereof. When the cooling gas is supplied from the cooling gas source 15 into the cabinet 12 through the cooling gas supply channel 13, the endless belt 10 that faces the inner space of the cabinet 12 is exposed to the cooling gas. Since the through-holes 16 are formed in the endless belt 10, the cooling gas comes into contact with the substrate 8 exposed to the through-holes 16, and further is introduced between the endless belt 10 and the substrate 8. The substrate 8 is cooled with the cooling gas while the material from the film forming source 27 is deposited on the surface of the substrate 8 that is being transferred linearly along the outer peripheral surface of the endless belt 10, and as a result, the deformation or melting of the substrate 8 is prevented.

As shown in FIG. 1, the substrate transfer mechanism 40 has a function of feeding the substrate 8 to a predetermined film forming section 4 that faces the film forming source 27, and a function of retracting, from the film forming section 4, the substrate 8 on which a film has been formed. The film forming section 4 is a section on the transfer path of the substrate 8. During the passage of the substrate 8 across this film forming section 4, the material coming from the film forming source 27 is deposited on the substrate 8, so that a thin film is formed on the substrate 8.

Specifically, the substrate transfer mechanism 40 is composed of a feed roller 2, guide rollers 3, and a take-up roller 5. The substrate 8 on which a film is to be formed is put on the feed roller 2. The guide rollers 3 are disposed on the upstream side and the downstream side, respectively, of the transfer direction of the substrate 8. The guide roller 3 on the upstream side guides the substrate 8 fed from the feed roller 2 to the endless belt 10. The guide roller 3 on the downstream side guides the substrate 8, on which the film has been formed, from the endless belt 10 to the take-up roller 5. The take-up roller 5 is driven by a motor (not shown), and takes up and holds the substrate 8 on which the thin film has been formed.

During the film formation process, the operation of feeding the substrate 8 from the feed roller 2 and the operation of taking up the substrate 8, on which the film has been formed, along the take-up roller 5 are performed in synchronization with each other. That is, the film forming apparatus 100 is a so-called take-up film forming apparatus for forming a thin film on the substrate 8 that is being transferred from the feed roller 2 toward the take-up roller 3. When such a take-up film forming apparatus is used, a long-time continuous film formation can be performed, which achieves high productivity.

Most of the material particles from the film forming source 27 are incident on the substrate 8 at oblique angles. More specifically, in the film forming apparatus 100, the material particles from the film forming source 27 are deposited on the substrate 8 that is moving linearly in the oblique direction with respect to the horizontal direction and the vertical direction (so-called oblique angle deposition). When a thin film is formed by oblique angle deposition, the resulting thin film has microvoids therein by the self-shadowing effect. Therefore, the oblique angle deposition is effective in manufacturing magnetic tapes with high C/N ratios (Carrier to Noise ratios) and negative electrodes for batteries having excellent cycle characteristics. The use of the endless belt 10 allows the substrate 8 to be transferred linearly in a relatively easy and stable manner.

In the present embodiment, the substrate 8 is an elongated substrate having flexibility. The material of the substrate 8 is not particularly limited. A polymer film or a metal foil can be used. Examples of the polymer film include a polyethylene terephthalate film, a polyethylene naphthalate film, a polyamide film, and a polyimide film. Examples of the metal foil include an aluminum foil, a copper foil, a nickel foil, a titanium foil, and a stainless steel foil. A composite material of a polymer film and a metal foil also can be used for the substrate 8.

The dimensions of the substrate 8 also are not particularly limited because they are determined according to the type of thin films to be manufactured and the production volume of the films. The width of the substrate 8 is, for example, 50 to 1000 mm, and the thickness of the substrate 8 is, for example, 3 to 150 μm.

During the film formation process, the substrate 8 is transferred at a constant speed. The transfer speed is, for example, 0.1 to 500 m/min, although it varies depending on the type of thin films to be manufactured and the film forming conditions. An appropriate tension is applied to the substrate 8 that is being transferred, depending on the material of the substrate 8, the dimensions of the substrate 8, the film forming conditions, etc.

The film forming source 27 is an evaporation source for evaporating the material by a heating method such as an electron beam, resistance heating, and induction heating. That is, the film forming apparatus 100 is a vacuum vapor deposition apparatus. The film forming source 27 is placed in the lower part of the vacuum chamber 1 so that the evaporated material travels vertically upward. As the film forming source 27, other film forming sources such as an ion plating source, a sputtering source, a chemical vapor deposition (CVD) source, and a plasma source may be used. A combination of a plurality of film forming sources also may be used. When an oxide or nitride thin film needs to be formed, a gas inlet pipe for introducing a source gas such as an oxygen gas or a nitrogen gas toward the space between the film forming source 27 and the substrate 8 is provided.

The shielding plate 7 is disposed between the film forming source 27 and the endless belt 10. The film forming area on the surface of the substrate 8 is defined by the opening portion of the shielding plate 7. The film forming area on the surface of the substrate 8 is an area that is not shielded by the shielding plate 7. In other words, the film forming area means an area on the substrate 8 that the material particles from the film forming source 27 can reach.

During the film formation process, the vacuum pump 9 is used to maintain the pressure of the vacuum chamber 1 at a level (for example, 1.0×10⁻² to 1.0×10⁻⁴ Pa) suitable for forming a thin film. As the vacuum pump 9, various types of vacuum pumps such as a rotary pump, an oil diffusion pump, a cryopump, and a turbomolecular pump can be used.

The endless belt 10 and the substrate cooling unit 30 are described further in detail.

As shown in FIG. 1, the endless belt 10 is hung between the two cans 11. When the cans 11 are driven by a motor or the like, the endless belt 10 moves. The transfer path of the substrate 8 in the film forming section 4 is defined along the outer peripheral surface of the endless belt 10. A thin film is formed on the surface of the substrate 8 that is being transferred linearly in the film forming section 4. The moving speed of the endless belt 10 during the film formation process is equal to the speed at which the substrate 8 is being transferred by the substrate transfer mechanism 40. The moving speed of the endless belt 10 and the transfer speed of the substrate 8 may be slightly different from each other as long as the difference does not cause a damage to the substrate 8.

The material of the endless belt 10 is not particularly limited. Metals such as stainless steel, titanium, molybdenum, copper, and titanium are preferably used from the viewpoint of heat resistance. The thickness of the endless belt 10 is, for example, 0.1 to 1.0 mm. The endless belt 10 having such a thickness is less susceptible to deformation by the radiant heat generated during the film formation process and the heat of the vapor stream, and is flexible enough to allow the use of the can 11 having a relatively small diameter.

The endless belt 10 may have a resin layer on its outer peripheral surface that is to be in contact with the substrate 8. That is, a metal belt lined with resin can be used as the endless belt 10. When a highly flexible resin layer is formed on the surface of the endless belt 10, the adhesion between the endless belt 10 and the substrate 8 is increased in the section where the endless belt 10 is in contact with the can 11. The adhesion between the endless belt 10 and a portion of the substrate 8 that is being transferred linearly also is increased slightly. As a result, the direct contact between the endless belt 10 and the substrate 8 increases the efficiency of cooling the substrate 8. Furthermore, the substrate 8 is less likely to slide on the endless belt 10, which prevents the back surface of the substrate 8 from being damaged.

The resin layer on the surface of the endless belt 10 is made of, for example, a material containing, as a main component (a component contained most in the material in terms of mass percentage), any of Teflon (registered trademark), silicone rubber, fluororubber, natural rubber, and petroleum-based synthetic rubber. The resin layer may contain a filler such as glass fiber to increase the mechanical durability of the resin layer.

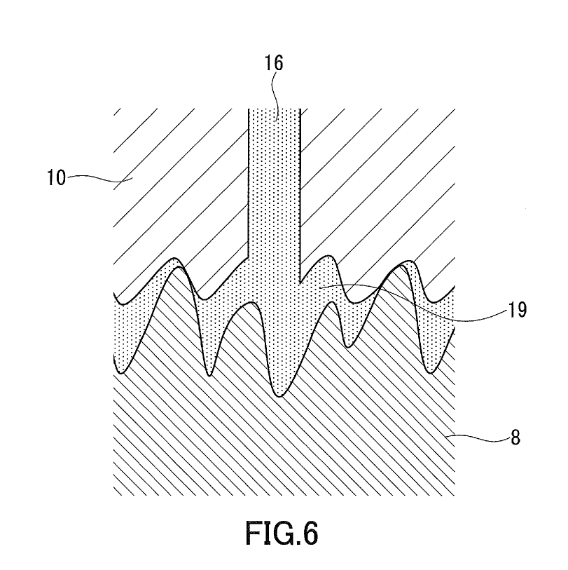

The substrate 8 may be attached to the endless belt 10 by electrostatic force to increase the contact portions between the endless belt 10 and the substrate 8. According to the present embodiment, as shown in FIG. 6, the cooling gas 19 can be introduced between the endless belt 10 and the substrate 8 through the through-holes 16. Therefore, even if the contact portions between the endless belt 10 and the substrate 8 increase, the cooling gas spreads over the surface of the substrate 8.

The endless belt 10 is in close contact with the can 11, and is cooled by the can 11. When the can 11 is used to cool the endless belt 10, the efficiency of cooling the substrate 8 can be increased accordingly based on the direct contact between the endless belt 10 and the substrate 8. To increase the area of contact between the can 11 and the endless belt 10 (to increase the adhesion therebetween), a flexible resin layer may be provided on the surface of the can 11. As the material of the resin layer, silicone rubber, fluororubber, natural rubber, petroleum-based synthetic rubber, or the like can be used. Such a resin layer is effective particularly when both of the can 11 and the endless belt 10 are made of metal. In addition to the can 11, a tension roller for applying tension to the endless belt 10 may be provided.

As shown in FIG. 2A, a plurality of the through-holes 16 are formed at equal distances along the longitudinal direction (orbital direction) of the endless belt 10. With this configuration, the substrate 8 can be cooled uniformly. The distance d between two through-holes 16 that are adjacent to each other in the longitudinal direction of the endless belt 10 is shorter than the length of the cabinet 12 in that direction. Therefore, the case where there is no through-hole 16 opening to the inside of the cabinet 12 can never happen, and the cooling gas can be introduced surely between the endless belt 10 and the substrate 8 through the through-holes 16.

More specifically, as shown in FIG. 2B, a plurality of rows of equally-spaced through-holes 16 are formed in the endless belt 10. With this configuration, the substrate 8 can be cooled uniformly in both of the longitudinal direction and the width direction. Accordingly, the surface of the substrate 8 is less likely to be cooled unevenly, and therefore the thermal deformation of the substrate 8 can be prevented reliably.

The opening area of each of the through-holes 16 is, for example, 0.5 to 20 mm². The through-holes having opening areas in this range are less susceptible to clogging of the material from the film forming source 27, and the cooling gas can be introduced between the endless belt 10 and the substrate 8 at a uniform pressure through the respective through-holes 16. When the cooling gas is introduced at a uniform pressure, the entire substrate 8 can be cooled uniformly, which is highly effective in reducing the deformation thereof.

The total opening area of the through-holes 16 is, for example, 0.2 to 20% of the film forming area. When the through-holes 16 are formed so that the total opening area thereof falls within this range, the cooling gas can be introduced between the endless belt 10 and the substrate 8 at a uniform pressure through the respective through-holes 16.

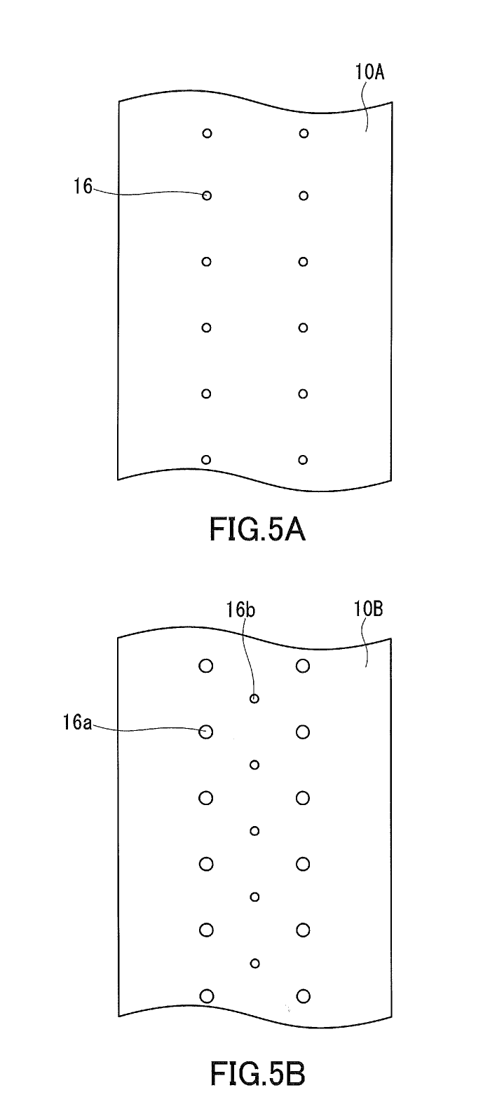

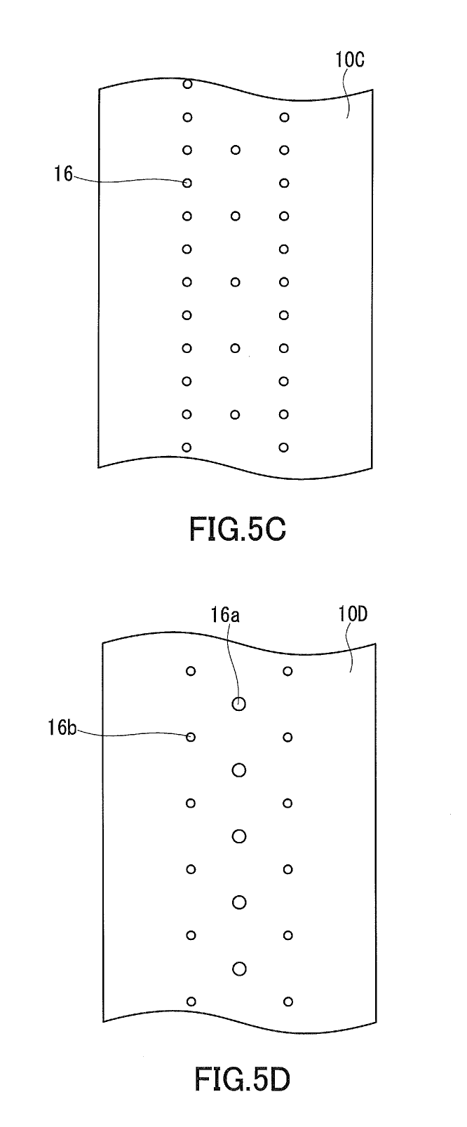

The arrangement of the through-holes 16 can be changed as appropriate. For example, in an endless belt 10A shown in FIG. 5A, the through-holes 16 are formed in two rows in the width direction of the endless belt 10A, and are formed, in each of the rows, at equal distances along the longitudinal direction of the endless belt 10A. In an endless belt 10B shown in FIG. 5B, through-holes 16a having a larger opening diameter and through-holes 16b having a smaller opening diameter are formed alternately in a staggered manner. That is, all the through-holes need not have the same opening area. In the endless belt 10B of FIG. 5B, the through-holes 16a having a relatively large opening diameter are located on both sides in the width direction of the endless belt 10B, and the through-holes 16b having a smaller opening diameter are located at the center row. Therefore, the entire substrate 8 including the edges thereof can be cooled sufficiently. In an endless belt 10C shown in FIG. 5C, three rows of through-holes 16 are formed. The rows located on both sides each have twice as many through-holes 16 as the central row. Therefore, the entire substrate 8 including the edges thereof can be cooled sufficiently. In an endless belt 10D shown in FIG. 5D, the positional relationship between the through-holes 16a and the through-holes 16b is reversed from that in the endless belt 10B in FIG. 5B. That is, the through-holes 16b having a smaller opening diameter are located on both sides in the width direction of the endless belt 10B, and the through-holes 16a having a larger opening diameter are located at the center row. This arrangement further ensures the cooling of the central portion of the substrate 8.

The opening shape of the through-holes is not limited to a circular shape. Various shapes such as a triangle, a square, and an ellipse can be used as appropriate. Groove-like through-holes may be formed. The number of rows of through-holes also is not limited to two or three. The number of rows may be four or more, or twenty or more in some cases.

As the cooling gas to be supplied to the cabinet 12, hydrogen, helium, carbon dioxide, argon, oxygen, nitrogen, water vapor, or the like can be used. A gas with a small molecular weight, for example, helium gas has high heat conductivity and thus high cooling capacity, and is less affected by the collision with the material particles from the film forming source 27.

As shown in FIG. 2A, the cabinet 12 opens toward the inner peripheral surface of the endless belt 10, and has a function of exposing the inner peripheral surface of the endless belt 10 to the cooling gas. The use of this cabinet 12 allows the cooling gas to go into a considerable number of through-holes 16 uniformly, and therefore, the almost entire substrate 8, on which a film is being formed in the film forming section 4, can be cooled uniformly. In the present embodiment, the cabinet 12 is a rectangular parallelepiped, but may have any other shape such as a dome shape.

There is no particular limitation on the material of the cabinet 12. The cabinet 12 can be fabricated by forming a metal plate or molding a resin. As shown in FIG. 2C, if the portion 12h that forms the opening edge 12e has a large thickness D1, the conductance of the gap 23 between the cabinet 12 and the endless belt 10 decreases. This makes the cooling gas flow less smoothly from the inside of the cabinet 12 to the outside thereof, and the pressure in the cabinet 12 increases. As a result, the cooling gas is introduced into the through-holes 16 more easily.

The width D₂ of the gap 23 between the opening edge 12e of the cabinet 12 and the inner peripheral surface of the endless belt 10 is constant with respect to the circumferential direction of the opening edge 12e of the cabinet 12. The width D₂ of the gap 23 is determined to be, for example, 0.1 to 1.0 mm (preferably, 0.2 to 0.5 mm), with respect to the thickness direction of the endless belt 10. The appropriately determined width D₂ of the gap 23 makes the cooling gas flow less smoothly from the inside of the cabinet 12 to the outside thereof through the gap 23 while avoiding the contact between the cabinet 12 and the endless belt 10.

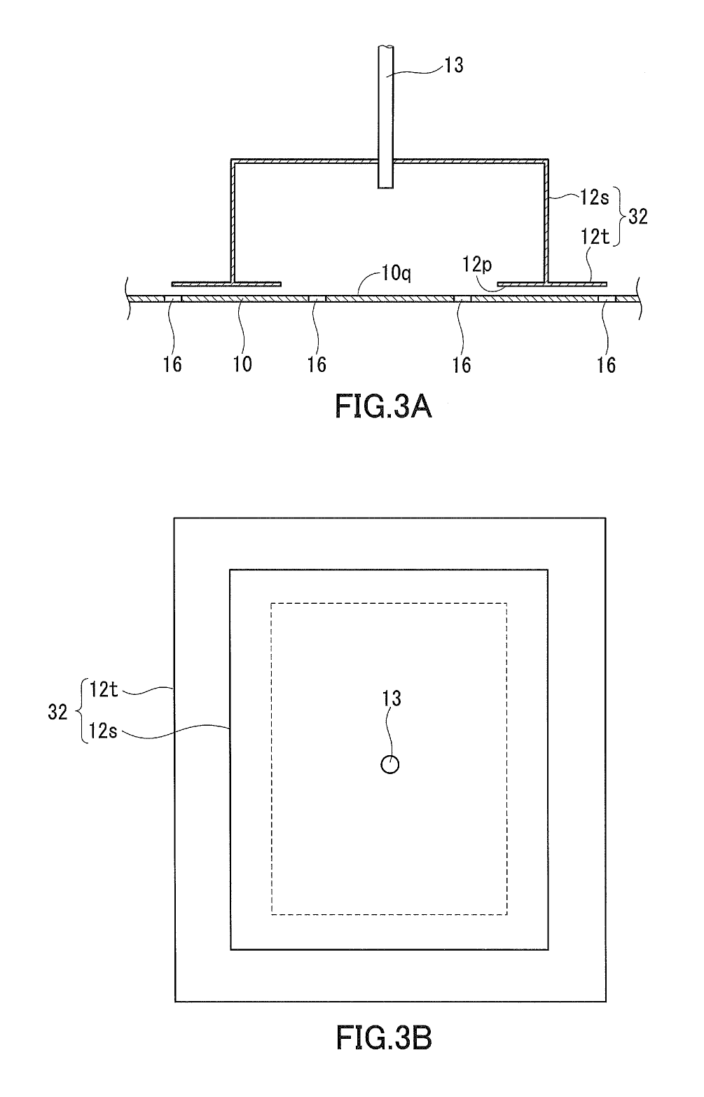

To obtain the above-mentioned effect, a structure for reducing the leakage conductance of the cooling gas may be provided. For example, a cabinet 32 shown in FIG. 3A and FIG. 3B is composed of a rectangular parallelepiped main body 12s opening toward the endless belt 10 and a plate-like flange portion 12t extending in the direction parallel to the inner peripheral surface 10q of the endless belt 10. The flange portion 12t has a frame shape in plan view (FIG. 3B). The flange portion 12t is provided to face the inner peripheral surface 10q of the endless belt 10 and forms the opening portion of the cabinet 32. The path from the inside of the cabinet 32 to the outside thereof is formed by the gap between the under surface 12p of the flange portion 12t and the inner peripheral surface 10q of the endless belt 10.

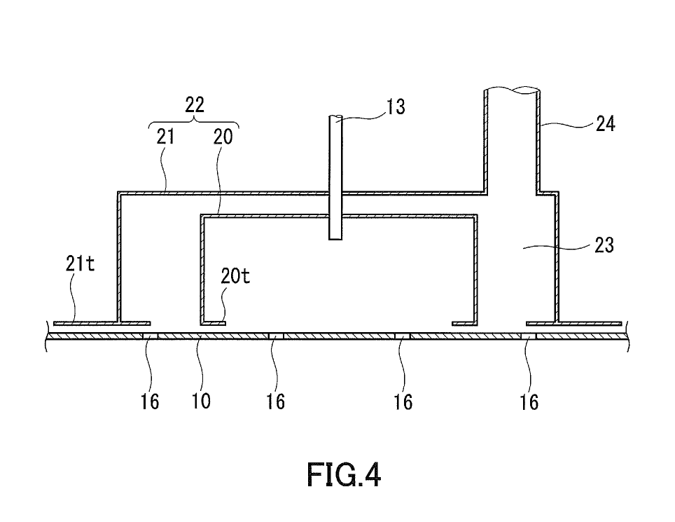

A structure for recovering the excess cooling gas further may be provided. Specifically, a cabinet 22 shown in FIG. 4 has a double structure including an inner portion 20 to which the gas supply channel 13 is connected and an outer portion 21 that covers the inner portion 20. A gas discharge channel (gas discharge pipe) 24 is connected to the outer portion 21 so that the cooling gas remaining in the space between the inner portion 20 and the outer portion 21 can be discharged directly to the outside of the vacuum chamber 1. This gas discharge channel 24 is connected to a vacuum pump (not shown) other than the vacuum pump 9 shown in FIG. 1. With this cabinet 22, even if the cooling gas leaks to the outside of the inner portion 20 through the gap between the inner portion 20 and the endless belt 10, the leaked cooling gas is trapped in the space 23 between the inner portion 20 and the outer portion 21 and discharged to the outside of the vacuum chamber 1 through the gas discharge channel 24. Accordingly, the film formation process can be performed in a higher vacuum. It is more effective to provide the flange portions 20t and 21t, which have been described with reference to FIG. 3A and FIG. 3B, on the inner portion 20 and the outer portion 21, respectively, of the cabinet 22.

The number of cooling gas supply channels 13 may be one as in the present embodiment. Two or more, or ten or more cooling gas supply channels 13 may be provided in some cases. A specific example of the cooling gas source 15 is a gas cylinder or a gas generating apparatus.

### Second Embodiment

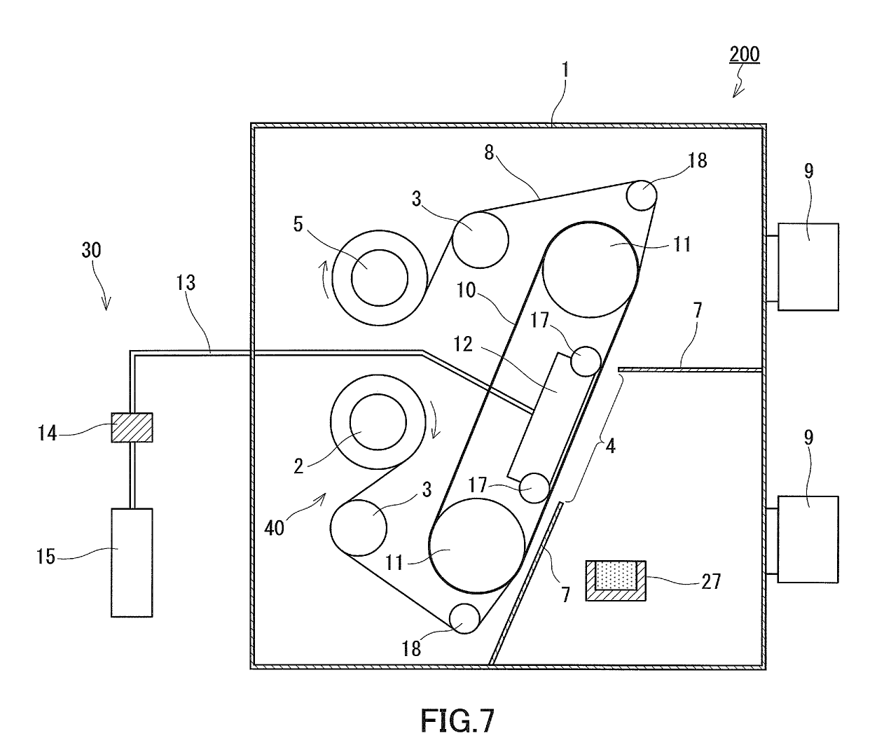

As shown in FIG. 7, according to a thin film forming apparatus 200 of the present embodiment, gap adjusting rollers 17 for adjusting the width of the gap between the endless belt 10 and the cabinet 12 are provided in the substrate cooling unit 30. Auxiliary rollers 18 for bringing the endless belt 12 into close contact with the substrate 8 are provided in the substrate transfer mechanism 40. Since the other components are the same as those of the thin film forming apparatus 100 of the first embodiment, the description thereof is omitted.

The gap adjusting rollers 17 are provided on the opening portion of the cabinet 12. With these gap adjusting rollers 17, the width of the gap between the cabinet 12 and the endless belt 10 can be maintained constant with high accuracy. As a result, the cabinet 12 is prevented from contacting and scratching the endless belt 10. Furthermore, if the gap between the cabinet 12 and the endless belt 10 is minimized to maintain the pressure in the cabinet 12, the cooling gas is introduced into the through-holes 16 more easily. In this case, only a small amount of cooling gas can produce a significant cooling effect, which is advantageous in suppressing the increase of the pressure in the vacuum chamber 1. A combination of the structure for recovering the excess cooling gas (see FIG. 4) and the gap adjusting rollers 17 is more effective.

As the gap adjusting rollers 17, rollers made of metal such as stainless steel or aluminum can be used. The surfaces of the gap adjusting rollers 17 may be made of rubber or plastic. The diameter of each of the gap adjusting rollers 17 is set to, for example 5 to 100 mm, to avoid occupying excessive installation space while ensuring sufficient strength.

The auxiliary rollers 18 are provided on the upstream side and the downstream side, respectively, of the transfer path of the substrate 8 with respect to the endless belt 10. The auxiliary rollers 18 are located closest to the endless belt 10 among the rollers on the transfer path of the substrate 8. When a film is formed on the substrate 8 that is being transferred linearly along the endless belt 10, it is difficult to apply tension to the substrate 8 that is being transferred in the film forming section 4 and therefore the substrate 8 and the endless belt 10 tend to be separated from each other. If the auxiliary roller 18 is provided at a position opposite to the film forming section 4, with the can 11 interposed between the film forming section 4 and that position (on each of the upstream side and the downstream side), tension is applied to the substrate 8 more easily. As a result, the substrate 8 is brought into suitably close contact with the endless belt 10.

### (Modification)

The number of film forming sections 4 is not limited to one. A plurality of film forming sections 4 may be present on the transfer path of the substrate 8. Specifically, an inverted V-shaped, a V-shaped, a W-shaped, or an M-shaped transfer path is formed and the film forming sources 27 are provided to face the respective sections for transferring the substrate 8 linearly. Films may be formed on both sides of the substrate 8. An additional can may be provided to cool the endless belt 10 sufficiently.

### INDUSTRIAL APPLICABILITY

The present invention can be applied to the manufacture of elongated electrode plates of energy storage devices. For example, a copper foil is used as the substrate 8, and silicon is used as the film forming material. Silicon is evaporated from the film forming source 27 to form a silicon film on the substrate 8. A thin film containing silicon and silicon oxide can be formed on the substrate 8 by introducing a trace amount of oxygen gas into the vacuum chamber 1. The copper substrate on which a silicon film has been formed can be used for the negative electrode of a lithium ion secondary battery.

Generally, a metal substrate is less elongated than a resin substrate when tension is applied thereto. Therefore, it is difficult to restore forcibly the metal substrate, once deformed, to the original shape by applying tension. As far as a lithium ion secondary battery using silicon as a negative-electrode active material is concerned, since a silicon film (or a film containing silicon and silicon oxide) expands when lithium is intercalated into the silicon lattice, the copper substrate as a collector is required to have sufficient strength. It is not desirable that the copper substrate be deformed by heat during the process of forming a silicon film because the deformation decreases the strength of the copper substrate or causes in-plane unevenness of strength of the substrate. When the present invention is applied, the deformation of the substrate can be prevented reliably. Therefore, a high performance negative electrode for a lithium ion secondary battery can be manufactured.

The present invention also is suitable for the manufacture of magnetic tapes. A polyethylene terephthalate film is used as the substrate 8, and cobalt is used as the film forming material. Cobalt is evaporated from the film forming source 27 while oxygen gas is introduced into the vacuum chamber 1. As a result, a film containing cobalt is formed on the substrate 8.

If the same type of gas is shared for both the cooling gas used in the substrate cooling unit 30 and the source gas for the thin film to use a part of the cooling gas as the source gas, the total amount of gas supplied into the vacuum chamber 1 may possibly be reduced.

The present invention can be applied not only to electrode plates of energy storage devices and magnetic tapes but also to capacitors, various sensors, solar cells, various optical films, moisture-proof films, and conductive films, which require film formation.

1. A thin film forming apparatus comprising:
a vacuum chamber;
a substrate transfer mechanism that is provided in the vacuum chamber and feeds an elongated substrate to a predetermined film forming section that faces a film forming source;
an endless belt capable of moving in accordance with the feeding of the substrate by the substrate transfer mechanism, and configured to define, along an outer peripheral surface of the endless belt itself, a transfer path of the substrate in the film forming section so that a thin film is formed on a surface of the substrate that is being transferred linearly;
a through-hole formed in the endless belt; and
a substrate cooling unit for introducing a cooling gas between the endless belt and a back surface of the substrate through the through-hole from a side of an inner peripheral surface of the endless belt that is moving.

2. The thin film forming apparatus according to claim 1, wherein the substrate cooling unit has: (a) a cabinet that is provided in a space surrounded by the endless belt and opens toward the inner peripheral surface of the endless belt in a section where the transfer path of the substrate is defined; and (b) a cooling gas supply channel whose one end is connected to the cabinet and whose other end extends to an outside of the vacuum chamber.

3. The thin film forming apparatus according to claim 2, wherein a plurality of the through-holes are formed at equal distances along a longitudinal direction of the endless belt.

4. The thin film forming apparatus according to claim 2, wherein
the cabinet has a plate-like flange portion that extends in a direction parallel to the inner peripheral surface of the endless belt and faces the inner peripheral surface, and
a gap between an under surface of the flange portion and the inner peripheral surface of the endless belt forms a path leading from an inside to an outside of the cabinet.

5. The thin film forming apparatus according to claim 2, wherein
the cabinet has a double structure including an inner portion to which the gas supply channel is connected and an outer portion that covers the inner portion, and
a gas discharge channel is connected to the outer portion so that the cooling gas remaining in a space between the inner portion and the outer portion can be discharged directly to the outside of the vacuum chamber.

6. The thin film forming apparatus according to claim 1, wherein the substrate transfer mechanism has an auxiliary roller for bringing the endless belt into close contact with the substrate.

7. The thin film forming apparatus according to claim 1, wherein
a plurality of the through-holes are formed in the endless belt, and
an opening area of each of the through-holes is 0.5 to 20 mm².

8. The thin film forming apparatus according to claim 1, further comprising a shielding portion that is disposed between the film forming source and the endless belt and defines a film forming area on the surface of the substrate,
wherein a plurality of the through-holes are formed in the endless belt, and
a total opening area of the through-holes is 0.2 to 20% of the film forming area.

9. The thin film forming apparatus according to claim 1, wherein the endless belt has a resin layer on its outer peripheral surface that is to be in contact with the substrate.

10. The thin film forming apparatus according to claim 1, further comprising a can for driving the endless belt and for cooling the endless belt.

11. A method of forming a thin film on an elongated substrate in a vacuum, the method comprising the steps of
depositing a material from a film forming source on a surface of the substrate that is being transferred linearly along an outer peripheral surface of an endless belt that defines a transfer path of the substrate; and
introducing a cooling gas between the endless belt and a back surface of the substrate through a through-hole formed in the endless belt, while carrying out the step of depositing the material.

12. The thin film forming method according to claim 11, wherein
a cabinet that opens toward an inner peripheral surface of the endless belt in a section where the transfer path of the substrate is defined is provided in a space surrounded by the endless belt, and
a cooling gas is supplied from an outside of a vacuum chamber into the cabinet so as to carry out the step of introducing the cooling gas.

13. The thin film forming method according to claim 12, wherein the substrate is made of a metal.
